(19) United States
(12) Patent Application Publication
(10) Pub. No.: US 2015/0366087 A1
(43) Pub. Date: Dec. 17, 2015

(54) Electronic Apparatus

(71) Applicant: FUJITSU TEN LIMITED, Kobe-shi (JP)

(72) Inventors: Kuniaki IDE, Kobe-shi (JP); Yuta YAMAGAMI, Kobe-shi (JP)

(73) Assignee: FUJITSU TEN LIMITED, Kobe-shi (JP)

(21) Appl. No.: 14/722,580

(22) Filed: May 27, 2015

(30) Foreign Application Priority Data
Jun. 13, 2014 (JP) 2014-122103

(51) Int. Cl. H05K 5/02; H05K 3/30; H05K 3/40; H05K 5/00

(52) U.S. Cl. CPC H05K 5/0204; H05K 5/0247; H05K 5/0026; H05K 3/30; H05K 3/4038

(57) ABSTRACT

A vehicle-mounted display apparatus includes a substrate and a sheet-metal holder. The substrate has through-holes penetrating a substrate surface of the substrate. In contrast, the sheet-metal holder includes a guide portion extending upright from a main surface of the sheet-metal holder, and projections projecting from the main surface of the sheet-metal holder and configured to define the position of the substrate with respect to the guide portion by an engagement with the through-holes. In a manufacturing process of the vehicle-mounted display apparatus, the substrate abuts against the guide portion in a state in which the substrate surface is inclined with respect to the main surface of the sheet-metal holder. Subsequently, the substrate rotates about the guide portion until the substrate surface becomes substantially parallel to the main surface of the sheet-metal holder, causing the through-holes and the projections to engage each other.

### BACKGROUND OF THE INVENTION

1. Field of the Invention

The present invention relates to an electronic apparatus provided with a substrate having components mounted thereon.

2. Description of the Related Art

In the related art, a substrate having electronic components mounted thereon is used in an electronic apparatus such as a display apparatus. In a manufacturing process of the electronic apparatus as described above, the substrate is fixed to an object member, which corresponds to an object to which the substrate is to be fixed, with a fastening member such as a screw. When fixing the substrate with respect to the object member, the substrate needs to be positioned at a correct position on the object member.

Known examples of a positioning structure for positioning the substrate as described above include a structure in which the object member is provided with a projection and the substrate is provided with a through-hole. A plurality of the projections are provided on the object member so as to project from a main surface thereof. In contrast, the substrate is provided with a plurality of the through-holes so as to penetrate a substrate surface. When placing the substrate on the object member, the plurality of projections provided on the object member are inserted into and engaged with the plurality of through-holes provided in the substrate respectively, so that the substrate may be positioned at the correct position on the object member.

A work of placing the substrate on the object member is generally performed by a worker. When the worker places the substrate on the object member, the main surface of the object member is hidden by the substrate. Therefore, the worker cannot figure out the position of the projections on the main surface of the object member, and hence positional alignment of the projections provided on the object member with the through-holes provided in the substrate is difficult. Consequently, when the worker places the substrate on the object member, the projections on the object member come into contact with the electronic components mounted in the peripheries of the through-holes, so that a risk of damage of the electronic components arises.

In order to prevent such an event, it is possible to determine a relatively large area in the peripheries of the through-holes as a prohibited range in which the electronic components are not allowed to be mounted. However, in recent years, a reduction in size of the substrate is required, and enlargement of the prohibited range is not desirable because a further reduction of an electronic-component-mountable surface area in the substrate.

### SUMMARY OF THE INVENTION

According to an aspect of the invention, an electronic apparatus includes: a substrate having (i) a component mounted thereon, (ii) a substrate surface, and (iii) a through-hole penetrating the substrate surface; and an object to which the substrate is to be fixed. The object includes: a main surface; a guide portion that extends upright from the main surface of the object; and a projection projecting from the main surface of the object, and configured to engage the through-hole penetrating the substrate surface of the substrate to define a position of the substrate with respect to the object. The electronic apparatus is manufactured by a process including: (a) abutting the substrate against the guide portion of the object in a state in which the substrate surface of the substrate is inclined with respect to the main surface of the object; and (b) rotating the substrate about the guide portion so that the substrate surface of the substrate reaches a state substantially parallel to the main surface of the object after the step of (a) to cause the projection to extend into the through-hole.

Since the projection provided on the object and the through-hole provided in the substrate engage by the substrate rotating after an abutment with the guide portion, positional alignment between the projection and the through-hole is easily achieved.

According to another aspect of the invention, the substrate includes: a connector configured to connect to a cable passing through an area in a vicinity of the guide portion when the substrate is fixed to the object, the guide portion includes a bent portion at which the guide portion is bent, one of sides of the guide portion is coupled to the main surface of the object, and an other of the sides of the guide portion extends in a direction opposite to a side of the guide portion on which the substrate abuts, and an outer periphery of the bent portion is a curved surface.

Even in the case where the cable comes into contact with the guide portion, the cable comes into contact mainly with the outer periphery of the bent portion having a curved surface, so that the cable may be prevented from becoming damaged.

Therefore, it is an object of the invention to facilitate positional alignment between a projection provided on an object member and a through-hole provided in a substrate.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a drawing illustrating an outline of a configuration of a vehicle-mounted display apparatus.

FIG. 2 is a perspective view illustrating a state in which a sheet-metal holder and a substrate are fixed to each other.

FIG. 3 is a perspective view illustrating a state in which the sheet-metal holder and the substrate are disassembled from each other.

FIG. 4 is a perspective view illustrating the sheet-metal holder.

FIG. 5 is a drawing illustrating a guide portion in an enlarged scale.

FIG. 6 is a cross-sectional view illustrating a cross section of the guide portion.

FIG. 7 is a drawing for explaining a method of placing the substrate on the sheet-metal holder.

FIG. 8 is a drawing for explaining the method of placing the substrate on the sheet-metal holder.

FIG. 9 is a side view illustrating the state in which the sheet-metal holder and the substrate are fixed to each other.

FIG. 10 is a plan view illustrating the state in which the sheet-metal holder and the substrate are fixed to each other.

### DESCRIPTION OF THE EMBODIMENTS

Hereinafter, an embodiment of the invention will be described with reference to the drawings. As an example of an electronic apparatus provided with a substrate having a component mounted thereon, a vehicle-mounted display apparatus used in a cabin of a vehicle will be described.

### 1. Outline of Apparatus

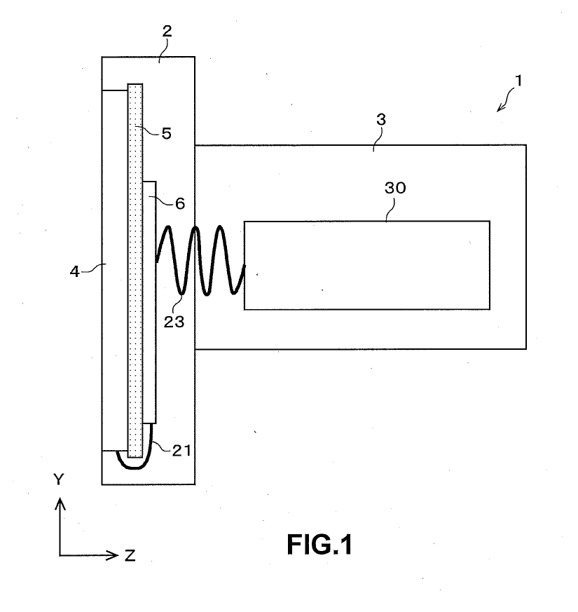

FIG. 1 is a drawing illustrating an outline of a configuration of a vehicle-mounted display apparatus 1 of this embodiment. The vehicle-mounted display apparatus 1 is provided with an audio function that outputs music, and is mounted on the vehicles such as automotive vehicles.

As illustrated, the vehicle-mounted display apparatus 1 includes a main body portion 3 and a panel portion 2. The main body portion 3 is provided with a control unit 30 that controls the vehicle-mounted display apparatus 1 as a whole. In contrast, the panel portion 2 is provided with a display 4 having a touch-panel function.

In the case where the vehicle-mounted display apparatus 1 is mounted on the vehicle, the main body portion 3 is accommodated in a center console or the like of the vehicle so that a screen of the display 4 of the panel portion 2 is exposed toward a user. In the following description, a display 4 side is expressed as a “front side”, and an opposite side to the display 4 is expressed as a “back side” in terms of a depth direction of the vehicle-mounted display apparatus 1.

The panel portion 2 further includes a sheet-metal holder 5 for holding the display 4 and a substrate 6 having various electronic components mounted thereon. The substrate 6 is electrically connected to the display 4 via a display cable 21, and to the control unit 30 via a control cable 23. Accordingly, the substrate 6 has a function that relays a signal between the display 4 and the control unit 30.

The display cable 21 and the control cable 23 employed in the invention are flexible cables which have flexibility and in which flat conductors are coated such as a flexible printed circuit (FPC) and a flexible flat cable (FFC). The control cable 23 configured to connect the substrate 6 and the control unit 30 is arranged in a state of being bent in an accordion manner.

The sheet-metal holder 5 holds a back side of the display 4. The substrate 6 is fixed to a back side of the sheet-metal holder 5. In a manufacturing process of the vehicle-mounted display apparatus 1, a worker in charge of manufacture places the substrate 6 on the sheet-metal holder 5, and then fixes the substrate 6 to the sheet-metal holder 5 with a screw. When the worker places the substrate 6 on the sheet-metal holder 5, the substrate 6 is positioned at a correct position on the sheet-metal holder 5, which is an object to which the substrate is to be fixed by means of a positioning structure which will be described below.

### 2. Sheet-Metal Holder and Substrate

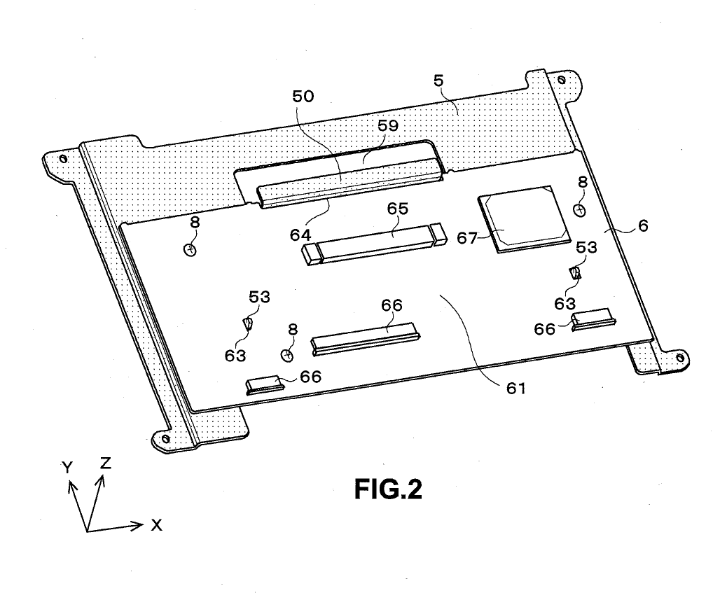

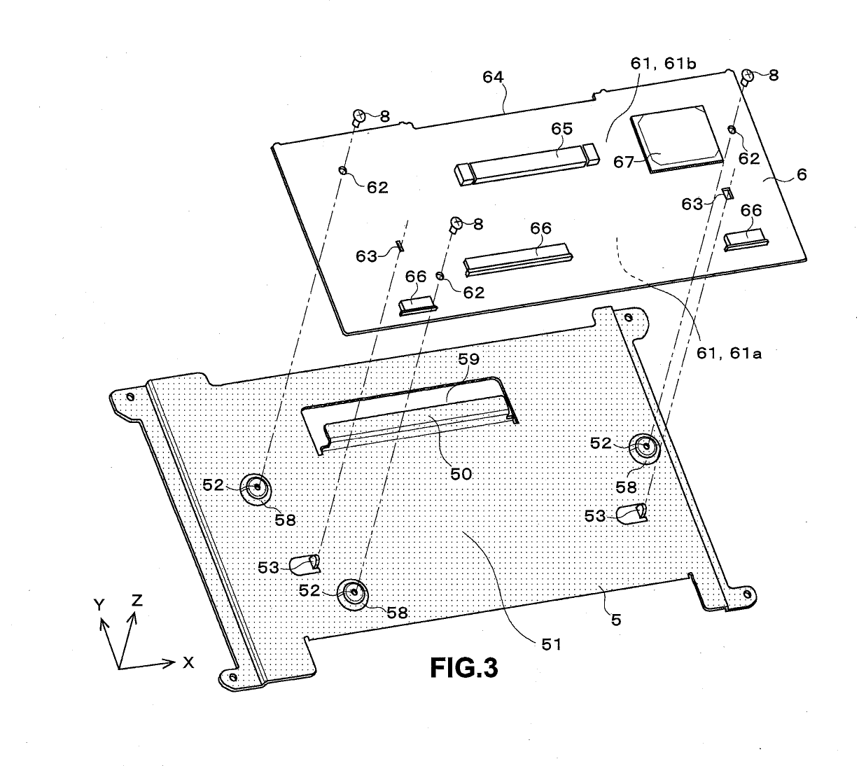

FIG. 2 is a perspective view illustrating a state in which the sheet-metal holder 5 and the substrate 6 are fixed to each other. FIG. 3 is an exploded perspective view illustrating a state in which the sheet-metal holder 5 and the substrate 6 are disassembled from each other. FIG. 2 and FIG. 3 illustrate a state viewed from the back side of the sheet-metal holder 5.

In the following description, directions and orientations are expressed as needed by using a three-dimensional orthogonal coordinate system (XYZ) illustrated in the drawing. The orthogonal coordinate system is fixed relatively with respect to the sheet-metal holder 5. An X-axis direction corresponds to a lateral direction of the display 4, a Y-axis direction corresponds to a vertical direction of the display 4, and a Z-axis direction corresponds to a depth direction of the vehicle-mounted display apparatus 1 (see also FIG. 1). A +X side corresponds to a left side of the screen of the display 4, and a −X side corresponds to a right side of the screen of the display 4. A +Y side corresponds to an upper side of the screen of the display 4, and a −Y side corresponds to a lower side of the screen of the display 4. A +Z side corresponds to a back side, and a −Z side corresponds to a front side.

The sheet-metal holder 5 is formed by processing a metallic plate such as a galvanized steel plate (SECC). As illustrated in FIG. 3, part of a main surface 51 of the sheet-metal holder 5 is provided with claw-shaped two projections 53 projecting from the main surface 51 to the back side (+Z side). Part of the main surface 51 of the sheet-metal holder 5 is provided with three projecting portions 58 swelling from the main surface 51 to the back side (+Z side). Screw holes 52 are provided at centers of the three projection portions 58.

The substrate 6 is a plate-shaped rigid substrate having electronic components mounted thereon. As illustrated, the substrate 6 includes various electronic components such as a communicating circuit 67 and connectors 65 and 66 for connecting to a cable mounted thereon. The first connector 65 connects to the control cable 23 configured to electrically connect the substrate 6 and the control unit 30, and three of the second connectors 66 connect to the display cable 21 configured to electrically connect the substrate 6 and the display 4 (See FIG. 1). In the drawing, although only part of the electronic components are illustrated for simplifying the description, various electronic components are actually mounted entirely of a substrate surface 61. In the drawing, only a substrate surface 61b on the back side (+Z side) of the substrate 6 is illustrated. However, various electronic components are mounted also on a substrate surface 61a on the front side (−Z side) of the substrate 6.

In contrast, the substrate 6 is provided with two through-holes 63 on the substrate surface 61 so as to penetrate the substrate surface 61. The two through-holes 63 provided in the substrate 6 allow the two projections 53 provided on the sheet-metal holder 5 to be inserted therein, respectively.

The substrate surface 61 of the substrate 6 is further provided with three screw holes 62. The three screw holes 62 provided in the substrate 6 correspond to the three screw holes 52 provided in the sheet-metal holder 5, respectively.

When the two projections 53 provided on the sheet-metal holder 5 are inserted and engaged respectively with the two through-holes 63 provided in the substrate 6, the substrate 6 may be positioned at a correct position on the sheet-metal holder 5. In other words, engagement between the two projections 53 and the two through-holes 63 restricts the movement of the substrate 6 in a direction parallel to the main surface 51 of the sheet-metal holder 5 (X-axis direction and Y-axis direction). Accordingly, the position of the substrate 6 in the direction parallel to the main surface 51 of the sheet-metal holder 5 is defined. Since the three projection portions 58 of the sheet-metal holder 5 abut against the substrate surface 61a on the front side (−Z side) of the substrate 6, the position of the substrate 6 in a direction orthogonal to the main surface 51 of the sheet-metal holder 5 (Z-axis direction) is also defined. Consequently, the position of the substrate 6 with respect to the sheet-metal holder 5, which is the object to which the substrate 6 is to be fixed, is defined.

When the substrate 6 is positioned at the correct position on the sheet-metal holder 5 in this manner, the positions of the three screw holes 62 provided in the substrate 6 and the three screw holes 52 provided in the sheet-metal holder 5 match. Therefore, the substrate 6 may be fixed to the sheet-metal holder 5 by using screws 8, which serve as fastening members, in these screw holes 52 and 62.

In the manufacturing process of the vehicle-mounted display apparatus 1, the worker places the substrate 6 on the sheet-metal holder 5 so that the positions of the projections 53 provided on the sheet-metal holder 5 and the positions of the through-holes 63 provided in the substrate 6 are aligned. The worker fixes the substrate 6 to the sheet-metal holder 5 by using the screws 8 in the screw holes 52 and 62 (see FIG. 2).

As a guide used when the worker places the substrate 6 on the sheet-metal holder 5 as described above, a guide portion 50 is provided on the main surface 51 of the sheet-metal holder 5. An engaging portion 64 formed so as to be depressed for allowing engagement with the guide portion 50 is provided at an edge portion of the +Y side of the substrate 6. The worker places the substrate 6 while making the substrate 6 abut against the guide portion 50, so that the positions of the projections 53 provided on the sheet-metal holder 5 and the positions of the through-holes 63 provided in the substrate 6 may be aligned easily.

### 3. Guide Portion

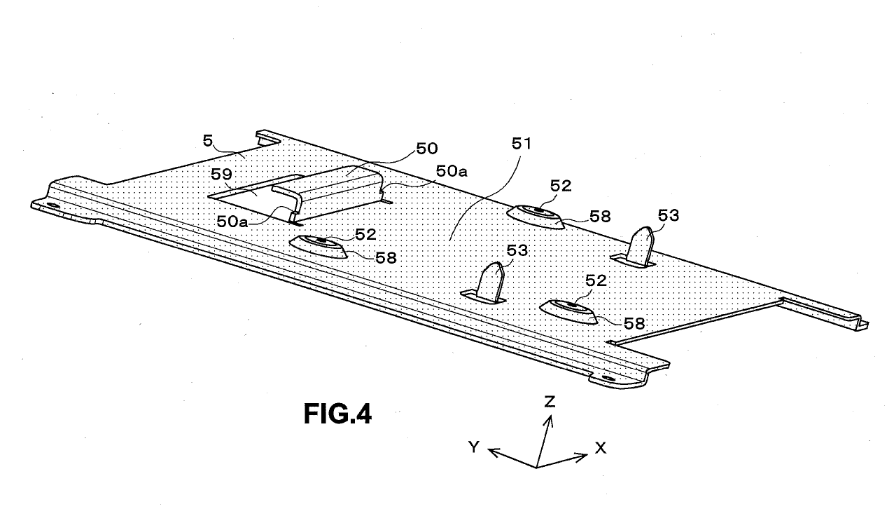

The guide portion 50 will be described below. FIG. 4 is a perspective view illustrating the sheet-metal holder 5 viewed in a direction different from those in FIG. 2 and FIG. 3. As illustrated, an opening 59 is formed on the +Y side of the main surface 51 of the sheet-metal holder 5, and the guide portion 50 is provided adjacent to the opening 59. The guide portion 50 is provided so as to extend upright from the main surface 51 of the sheet-metal holder 5 on the back side (+Z side).

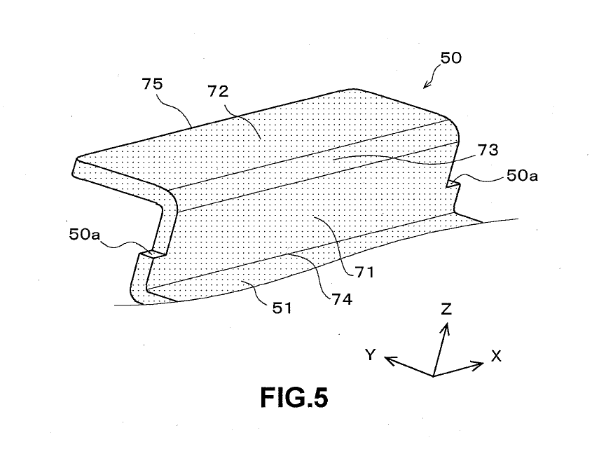

FIG. 5 is a drawing illustrating the guide portion 50 illustrated in FIG. 4 in an enlarged scale. As illustrated in FIG. 5, the guide portion 50 extends along the X-axis direction. One side of the guide portion 50 extending along the X-axis direction thereof corresponds to a coupled side 74, which is to be coupled to the main surface 51 of the sheet-metal holder 5, and the other side corresponds to an opened side 75, which is not to be coupled to the main surface 51 and is opened.

The guide portion 50 is bent at a bent portion 73 so that the opened side 75 faces outside of the sheet-metal holder 5. The bent portion 73 extends along the X-axis direction. Accordingly, the guide portion 50 is a member having a substantially L-shaped cross section including a vertical surface 71 extending substantially orthogonally to the main surface 51 of the sheet-metal holder 5 while extending along the X-axis direction and a parallel surface 72 substantially parallel to the main surface 51 of the sheet-metal holder 5 while extending along the X-axis direction.

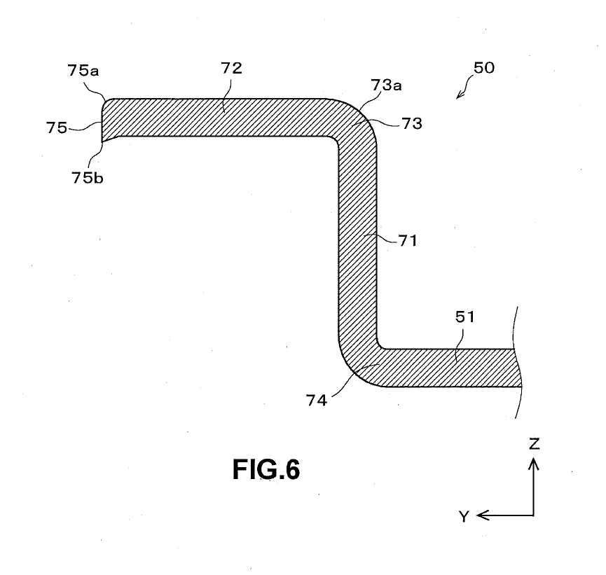

FIG. 6 is a cross-sectional view illustrating a cross section of the guide portion 50 viewed from the −X side. As illustrated, the guide portion 50 is bent by a substantially right angle at the bent portion 73, which corresponds to a connecting portion with respect to the vertical surface 71 and the parallel surface 72. Accordingly, the cross section of the guide portion 50 has a substantially L-shape. An outer periphery 73a of the bent portion 73 is a curved surface. When making the substrate 6 abut against the guide portion 50, the substrate 6 abuts against the vertical surface 71 from the −Y side (detail description will be given below). Therefore, the opened side 75 of the guide portion 50 is directed to a side (+Y side) opposite to a side (−Y side) against which the substrate 6 abuts.

The guide portion 50 as described above is formed by press work on part of a metallic plate, which is a material of the sheet-metal holder 5. The opening 59 (see FIG. 4) and a rectangular strip, which corresponds to an intermediate member of the guide portion 50 are formed by a punching process of a main surface of the metallic plate (the main surface 51 of the sheet-metal holder 5). In addition, the guide portion 50 is formed by a bending process of the rectangular strip. As a result of the press work (mainly, punching) in this manner, phenomena referred to as “rollover” and “burr” occur on the opened side 75 of the guide portion 50.

As illustrated in FIG. 6, the “rollover”, which is a phenomenon that a corner is rounded, occurs at an edge portion 75a on the back side (+Z side) of the opened side 75. In other words, the “rollover” caused by the press work occurs on the side (+Z side) on which the guide portion 50 extends upright from the main surface 51 of the sheet-metal holder 5. In contrast, the “burr”, which is a phenomenon that a metallic extending point is generated, occurs at an edge portion 75b on the front side (−Z side) of the opened side 75.

Returning back to FIG. 5, the guide portion 50 is provided with projecting strips 50a projecting outward in the X-axis direction on lower portions of both end portions of the vertical surface 71 in the X-axis direction so as to form steps at the both end portions. The projecting strips 50a are configured to retain the substrate 6 temporarily when the worker makes the substrate 6 abut against the vertical surface 71 of the guide portion 50.

### 4. Placement of Substrate

Subsequently, a method that the worker places the substrate 6 on the sheet-metal holder 5 by using the guide portion 50 in this manner will be described.

As illustrated in FIG. 4, the worker arranges the sheet-metal holder 5 on a working table or the like so that the main surface 51 of the sheet-metal holder 5 extends substantially horizontally.

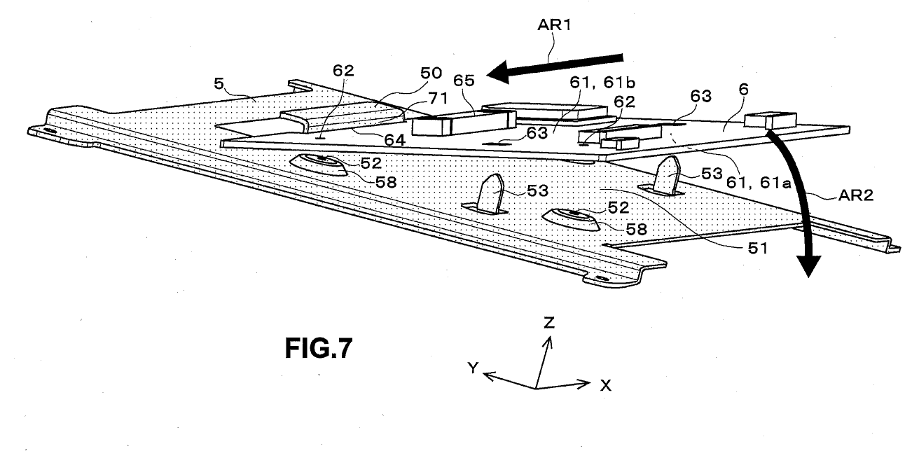

Subsequently, as illustrated in FIG. 7, the worker makes the substrate 6 abut against the guide portion 50 from the −Y side in a state in which the substrate surface 61 of the substrate 6 is inclined with respect to the main surface 51 of the sheet-metal holder 5 (an arrow AR1 in the drawing). The worker then engages the engaging portion 64 of the substrate 6 with the vertical surface 71 of the guide portion 50. At this time, the projecting strips 50a provided at both end portions of the guide portion 50 retain both outer sides of the engaging portion 64 of the substrate 6. Accordingly, the edge portion including the engaging portion 64 of the substrate 6 extends along the X-axis direction and is retained at a substantially fixed distance from the main surface 51 of the sheet-metal holder 5.

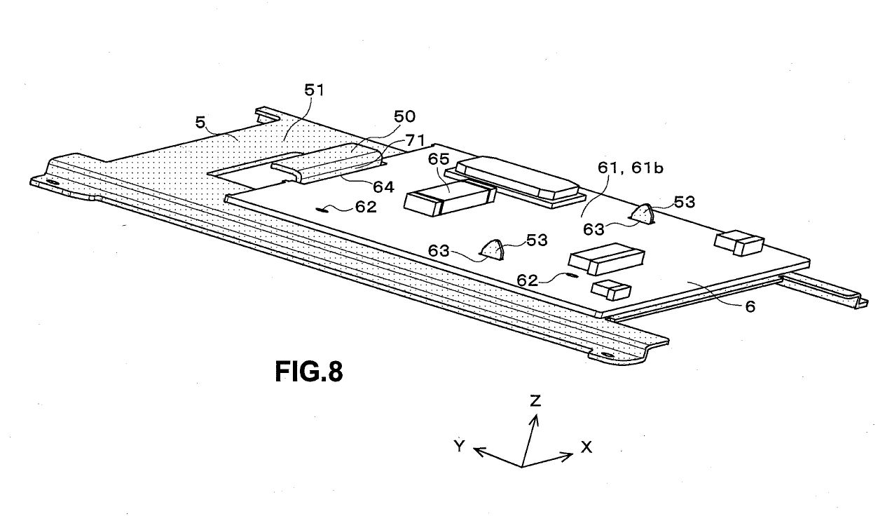

Subsequently, the worker moves the edge portion on the opposite side from the engaging portion 64 of the substrate 6 toward the main surface 51 of the sheet-metal holder 5 while maintaining the abutting state between the engaging portion 64 of the substrate 6 and the guide portion 50. Accordingly, the worker rotates the substrate 6 about the guide portion 50 extending along the X-axis direction (an arrow AR2 in the drawing). The worker continues to rotate the substrate 6 in this manner until the substrate surface 61 of the substrate 6 becomes substantially parallel to the main surface 51 of the sheet-metal holder 5 as illustrated in FIG. 8.

The positional relationship between the two projections 53 with respect to the guide portion 50 on the sheet-metal holder 5 and the positional relationship of the two through-holes 63 with respect to the engaging portion 64 of the substrate 6 are substantially the same. Therefore, in the course of rotation of the substrate 6, the positions of the two projections 53 provided on the sheet-metal holder 5 and the positions of the two through-holes 63 provided in the substrate 6 are aligned automatically, and the two projections 53 are inserted into the two through-holes 63, respectively.

When the substrate surface 61 becomes substantially parallel to the main surface 51 of the sheet-metal holder 5, the two projections 53 provided on the sheet-metal holder 5 and the two through-holes 63 provided in the substrate 6 engage each other. Consequently, the substrate 6 is positioned at a correct position on the sheet-metal holder 5.

In this manner, in the positioning structure of the vehicle-mounted display apparatus 1 of this embodiment, the substrate 6 is provided with the through-holes 63 that penetrate the substrate surface 61 of the substrate 6. In contrast, the sheet-metal holder 5 includes the guide portion 50 provided so as to extend upright from the main surface 51 of the sheet-metal holder 5, and the projections 53 projecting from the main surface of the sheet-metal holder 5 and configured to define the position of the substrate 6 with respect to the guide portion 50 by an engagement with the through-holes 63.

In the manufacturing process of the vehicle-mounted display apparatus 1, the substrate 6 abuts against the guide portion 50 in the state in which the substrate surface 61 is inclined with respect to the main surface 51 of the sheet-metal holder 5. Subsequently, the substrate 6 rotates about the guide portion 50 until the substrate surface 61 becomes substantially parallel to the main surface 51 of the sheet-metal holder 5. Accordingly, the through-holes 63 and the projections 53 engage each other.

Therefore, the worker achieves positional alignment between the projections 53 provided on the sheet-metal holder 5 and the through-holes 63 provided in the substrate 6 only by a simple operation of rotating the substrate 6 after making the substrate 6 abut against the guide portion 50. Therefore, the projections 53 provided on the sheet-metal holder 5 may be prevented from coming into contact with the electronic components mounted on the substrate 6, and hence damages of the electronic components may be prevented effectively. Since the positions of the projections 53 and the through-holes 63 may be aligned accurately, the prohibited range in the periphery of the through-holes 63 on the substrate surface 61a on the front side (−Z side) of the substrate 6, in which the electronic components are not allowed to be mounted may be reduced.

### 5. Prevention of Damage of Cable

The above-described guide portion 50 is provided so as to extend upright from the main surface 51 of the sheet-metal holder 5, and when the substrate 6 is fixed to the sheet-metal holder 5, the first connector 65 is arranged in the proximity to the guide portion 50. Therefore, when the control cable 23 (see FIG. 1) is connected to the first connector 65 of the substrate 6, the control cable 23 and the guide portion 50 may come into contact with each other. In the positioning structure of the vehicle-mounted display apparatus 1 of this embodiment, even though the control cable 23 comes into contact with the guide portion 50 in this manner, the control cable 23 is prevented from becoming damaged.

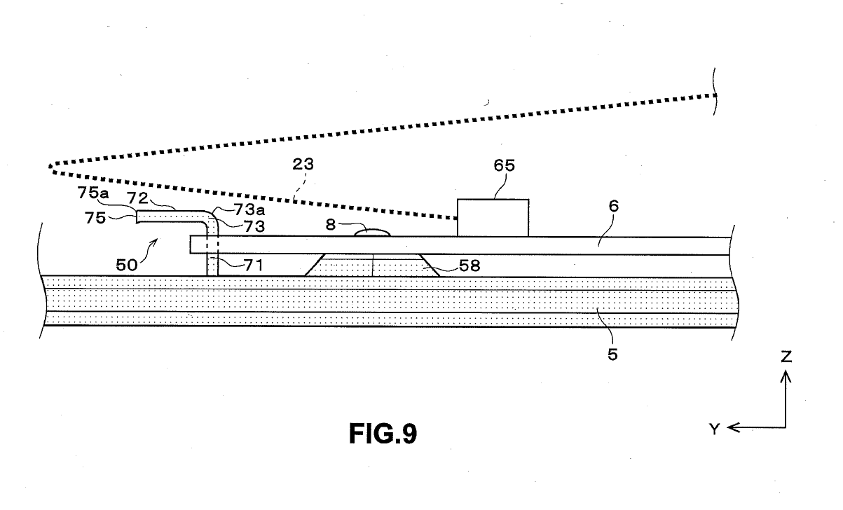

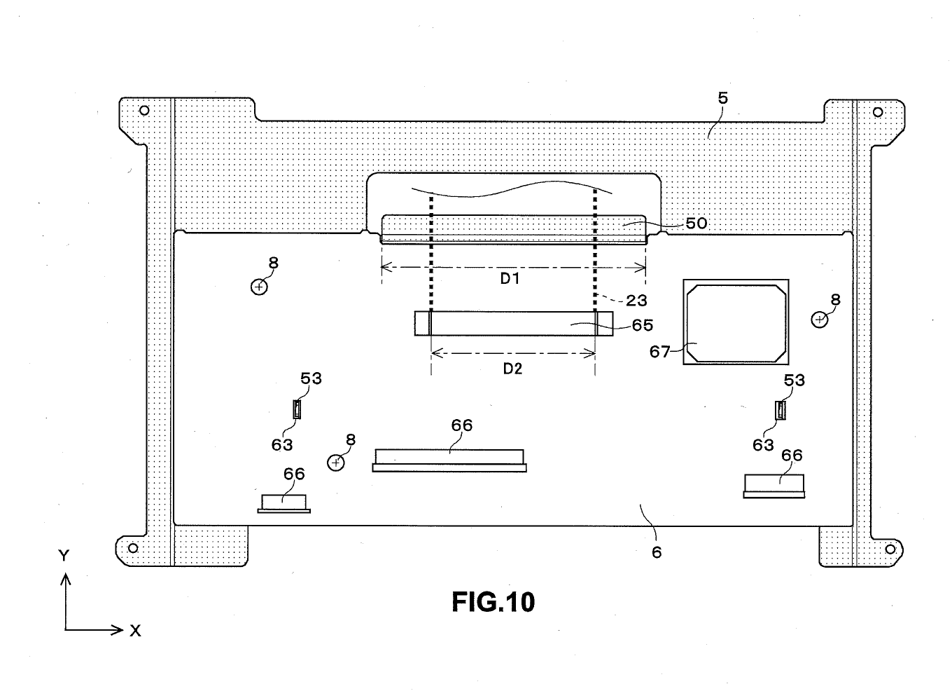

FIG. 9 is a side view illustrating the state in which the sheet-metal holder 5 and the substrate 6 are fixed to each other viewed from the −X side. FIG. 10 is a plan view illustrating the state in which the sheet-metal holder 5 and the substrate 6 are fixed to each other viewed from the +Z side. In these drawings, the position of the control cable 23 connected to the first connector 65 is illustrated by a broken line. As illustrated in these drawings, since the control cable 23 passes through a position in the vicinity of the guide portion 50, the control cable 23 and the guide portion 50 may come into contact with each other.

As described above, the guide portion 50 is bent at the bent portion 73, and the opened side 75 faces to a side (+Y side) opposite to the side (−Y side) against which the substrate 6 abuts. Therefore, as illustrated in FIG. 9, the opened side 75 is arranged on the side (+Y side) opposite to the side where the first connector 65 provided on the substrate 6 is present, and the bent portion 73 is arranged on the side (−Y side) where the first connector 65 is present. Therefore, even in the case where the control cable 23 comes into contact with the guide portion 50, the control cable 23 comes into contact mainly with the outer periphery 73a of the bent portion 73 having a curved surface, so that the control cable 23 may be prevented from becoming damaged.

The guide portion 50 is a member having a substantially L-shaped cross section including the vertical surface 71 extending substantially orthogonally to the main surface 51 of the sheet-metal holder 5 and the parallel surface 72 substantially parallel to the main surface 51 of the sheet-metal holder 5. Therefore, even in the case where the control cable 23 comes into contact with a portion other than the bent portion 73 of the guide portion 50, the control cable 23 comes into contact mainly with the parallel surface 72 substantially parallel to the main surface 51 of the sheet-metal holder 5, so that the control cable 23 may be prevented from becoming damaged.

In addition, on the opened side 75 of the guide portion 50, the “rollover” caused by the press work occurs at the edge portion 75a on the side (+Z side) on which the guide portion 50 extends upright from the main surface 51 of the sheet-metal holder 5 (see FIG. 6). Therefore, even in the case where the control cable 23 comes into contact with the opened side 75 of the guide portion 50, the control cable 23 comes into contact with the side where the rounded “rollover” occurs, so that the control cable 23 may be prevented from becoming damaged.

As illustrated in FIG. 10, the guide portion 50 and the first connector 65 are both arranged so as to extend in the X-axis direction, and the centers of the guide portion 50 and the first connector 65 in the X-axis direction are substantially aligned. A size D1 of the guide portion 50 in a direction (X-axis direction) substantially orthogonal to a direction (substantially Y-axis direction) in which the control cable 23 passes is larger than a width D2 of the control cable 23. Therefore, the position of the guide portion 50 includes the position where the control cable 23 passes. Therefore, even in the case where the control cable 23 comes into contact with the guide portion 50, the control cable 23 does not come into contact with the both end portions of the guide portion 50 in the X-axis direction, the control cable 23 is prevented from becoming damaged.

### 6. Modifications

Although the embodiment of the invention has been described thus far, the invention is not limited to the embodiment described above, and various modifications may be made. Such modifications will be described below. All of the modes including the above-described embodiment and modes described below may be combined as needed.

In the above-described embodiment, the guide portion 50 is a member having the substantially L-shape in cross section. However, the guide portion 50 may be a plate-shaped member provided so as to simply extend upright from the main surface 51 of the sheet-metal holder 5. In this case as well, a portion which may come into contact with the cable (for example, the opened side which is not coupled to the main surface 51) is preferably formed into a curved surface in order to prevent the cable from becoming damaged.

In the embodiment described above, the object to which the substrate 6 is to be fixed, is the sheet-metal holder 5 formed by processing the metallic plate. However, the invention is not limited thereto. The object to which the substrate is to be fixed, may be, for example, a resin molded by using a metal mold.

In the above-described embodiment, the flexible cables are employed as the cables. However, other types of cables such as flat cables are also applicable.

In the above-described embodiment, the vehicle-mounted display apparatus used in the cabin of the vehicle has been descried. However, the invention is not limited thereto. The technology as described above is applicable to any types of the electronic apparatus as long as the substrate having the components mounted thereon is used.

While the invention has been shown and described in detail, the foregoing description is in all aspects illustrative and not restrictive. It is therefore understood that numerous other modifications and variations can be devised without departing from the scope of the invention.

What is claimed is:

1. An electronic apparatus comprising:
a substrate having (i) a component mounted thereon, (ii) a substrate surface, and (iii) a through-hole penetrating the substrate surface; and
an object to which the substrate is to be fixed,
wherein
the object includes:
a main surface;
a guide portion that extends upright from the main surface of the object; and
a projection projecting from the main surface of the object, and configured to engage the through-hole penetrating the substrate surface of the substrate to define a position of the substrate with respect to the object,
wherein
the electronic apparatus is manufactured by a process including:
(a) abutting the substrate against the guide portion of the object in a state in which the substrate surface of the substrate is inclined with respect to the main surface of the object; and
(b) rotating the substrate about the guide portion so that the substrate surface of the substrate reaches a state substantially parallel to the main surface of the object after the step of (a) to cause the projection to extend into the through-hole.

2. The electronic apparatus according to claim 1, wherein
the substrate includes:
a connector configured to connect to a cable passing through an area in a vicinity of the guide portion when the substrate is fixed to the object,
the guide portion includes a bent portion at which the guide portion is bent,
one of sides of the guide portion is coupled to the main surface of the object, and an other of the sides of the guide portion extends in a direction opposite to a side of the guide portion on which the substrate abuts, and
an outer periphery of the bent portion is a curved surface.

3. The electronic apparatus according to claim 2, wherein
the guide portion has a substantially L-shaped cross section including a first surface extending substantially orthogonally to the main surface of the object and a second surface extending substantially in parallel to the main surface of the object.

4. The electronic apparatus according to claim 2, wherein
a size of the guide portion in a direction extending substantially orthogonally to a direction in which the cable passes is larger than a width of the cable.

5. The electronic apparatus according to claim 2, wherein
the guide portion is formed by a press work on a metallic plate, and
rollover caused by the press work occurs on a side on which the guide portion extends upright from the main surface of the object on the other side of the guide portion.

6. A method of manufacturing an electronic apparatus that includes (A) a substrate having (i) a component mounted thereon, (ii) a substrate surface, and (iii) a through-hole penetrating the substrate surface; and (B) an object to which the substrate is to be fixed, the object including (1) a main surface, (2) a guide portion that extends upright from the main surface of the object, and (3) a projection projecting from the main surface of the object, and configured to engage the through-hole penetrating the substrate surface of the substrate to define a position of the substrate with respect to the object,
the method of manufacturing the electronic apparatus comprising:
(a) abutting the substrate against the guide portion of the object in a state in which the substrate surface of the substrate is inclined with respect to the main surface of the object; and
(b) rotating the substrate about the guide portion so that the substrate surface of the substrate reaches a state substantially parallel to the main surface of the object after the step of (a) to cause the projection to extend into the through-hole.

7. An electronic apparatus comprising:
a substrate having (i) a component mounted thereon, (ii) a substrate surface, and (iii) a through-hole penetrating the substrate surface; and
an object to which the substrate is fixed, the object including (1) a main surface, (2) a guide portion that extents upright from the main surface of the object, and (3) a projection projecting from the main surface of the object, and configured to engage the through-hole penetrating the substrate surface of the substrate to define a position of the substrate with respect to the object, wherein
the substrate abuts against the guide portion of the object,
the substrate surface of the substrate is substantially parallel to the main surface of the object, and
the projection extends into the through-hole.

8. The electronic apparatus according to claim 7, wherein
the substrate includes:
a connector configured to connect to a cable passing through an area in a vicinity of the guide portion when the substrate is fixed to the object,
the guide portion includes a bent portion at which the guide portion is bent,
one of sides of the guide portion is coupled to the main surface of the object, and an other of the sides of the guide portion extends in a direction opposite to a side of the guide portion on which the substrate abuts, and
an outer periphery of the bent portion is a curved surface.

9. The electronic apparatus according to claim 8, wherein
the guide portion has a substantially L-shaped cross section including a first surface extending substantially orthogonally to the main surface of the object and a second surface extending substantially in parallel to the main surface of the object.

10. The electronic apparatus according to claim 8, wherein
a size of the guide portion in a direction extending substantially orthogonally to a direction in which the cable passes is larger than a width of the cable.

11. The electronic apparatus according to claim 8, wherein
the guide portion is formed by a press work on a metallic plate, and
rollover caused by the press work occurs on a side on which the guide portion extends upright from the main surface of the object on the other side of the guide portion.
